(19) United States
(12) Patent Application Publication
(10) Pub. No.: US 2026/0075932 A1
(43) Pub. Date: Mar. 12, 2026

(54) INTEGRATED CIRCUIT DEVICE

(71) Applicant: SAMSUNG ELECTRONICS CO., LTD., SUWON-SI (KR)

(72) Inventor: MYOUNGSOO KIM, SUWON-SI (KR)

(21) Appl. No.: 19/083,498

(22) Filed: Mar. 19, 2025

(30) Foreign Application Priority Data
Sep. 11, 2024 (KR) 10 -2024-0124242

(51) Int. Cl. H10D 84/83; H10D 64/27

(52) U.S. Cl. CPC H10D 84/83138; H10D 64/513; H10D 84/8312

(57) ABSTRACT

An integrated circuit device includes a substrate having an active region defined by a device isolation film, a recess trench disposed in the active region, spaced apart from the device isolation film, and extending in a vertical direction from a main surface of the substrate towards an interior of the substrate, and a recess channel transistor including a gate electrode disposed within the recess trench, the recess channel transistor including a channel positioned along a surface of the recess trench, wherein each of the recess trench and the gate electrode has a closed-loop shape in a plan view.

### CROSS-REFERENCE TO RELATED APPLICATION

This U.S. patent application claims priority under 35 U.S.C. § 119 to Korean Patent Application No. 10-2024-0124242, filed on Sep. 11, 2024, in the Korean Intellectual Property Office, the disclosure of which is incorporated by reference in its entirety herein.

### 1. Technical Field

Embodiments of the inventive concept are directed to an integrated circuit device, and more particularly, to an integrated circuit device including a transistor.

### 2. Discussion of Related Art

An integrated circuit (IC) is a miniaturized electronic circuit consisting of multiple interconnected components such as transistors, resistors, capacitors, and diodes, all fabricated on a single semiconductor substrate (usually silicon). ICs are designed to perform various functions, including signal processing, computation, amplification, and power management. An integrated circuit device may include one or more ICs.

As the electronics industry has advanced, the integration level of integrated circuit devices has progressively increased. Consequently, optimized designs are needed to enhance the reliability of integrated circuit devices while minimizing their footprint. Display driver integrated circuits (DDIs) for driving display devices, such as liquid-crystal display devices (LCDs) or plasma display panels (PDPs) are examples of integrated circuit devices. DDIs include transistors with a wide range of operating voltages.

DDIs include high-voltage transistors operating at relatively high operating voltages. High-voltage transistors typically occupy a large area due to the need for extended drift regions, thicker gate oxides, and longer channel lengths to sustain high operating voltages while preventing breakdown. Additionally, these transistors often exhibit a hump phenomenon in their transfer characteristics, which arises from unintended edge channels forming near the interface between the device isolation region and the active region. These parasitic conduction paths can lead to an unexpected increase in drain current, affecting device performance and reliability. Furthermore, high-voltage transistors are susceptible to threshold voltage variations due to process fluctuations, charge trapping at the isolation interface, and hot carrier effects, which can degrade performance over time.

### SUMMARY

The inventive concept provides an integrated circuit device with the intended performance with a minimum area in a highly reduced area by reducing an occupied area of a high-voltage transistor as well as by preventing the formation of an unintended edge channel in the vicinity of an interface between a device isolation region and an active region in the high-voltage transistor and preventing a reduction in threshold voltage through the suppression of a hump phenomenon.

According to an aspect of the inventive concept, there is provided an integrated circuit device including a substrate including an active region defined by a device isolation film, a recess trench disposed in the active region and spaced apart from the device isolation film, the recess trench extending in a vertical direction from a main surface of the substrate towards an interior of the substrate, and a recess channel transistor including a gate electrode that is disposed within the recess trench, the recess channel transistor including a channel positioned along a surface of the recess trench, wherein each of the recess trench and the gate electrode has a closed-loop shape in a plan view.

According to another aspect of the inventive concept, there is provided an integrated circuit device including a substrate including an active region defined by a device isolation film, and a recess channel transistor disposed in the active region, wherein the recess channel transistor includes a first recess trench disposed in the active region and spaced apart from the device isolation film, the first recess trench extending in a vertical direction from a main surface of the substrate towards an interior of the substrate, a first gate electrode including a buried electrode portion and a protruding electrode portion, the buried electrode portion filling the first recess trench, and the protruding electrode portion being integrally connected to the buried electrode portion and protruding above the main surface of the substrate, and a plurality of source/drain regions, each of the first recess trench and the first gate electrode has a closed-loop shape in a plan view, and one source/drain region among the plurality of source/drain regions is surrounded by the first gate electrode in a plan view.

According to another aspect of the inventive concept, there is provided an integrated circuit device including a substrate including an active region defined by a device isolation film, a recess trench disposed in the active region and spaced apart from the device isolation film, the recess trench extending in a vertical direction from a main surface of the substrate towards an interior of the substrate, and a recess channel transistor including a channel positioned along a surface of the recess trench, wherein the recess channel transistor includes a gate dielectric film covering an inner wall of the recess trench, a gate electrode including a buried electrode portion and a protruding electrode portion, the buried electrode portion being disposed on the gate dielectric film and within the recess trench, and the protruding electrode portion being integrally connected to the buried electrode portion and protruding above the main surface of the substrate, a first source/drain region in a first active region of the active region, the first active region being surrounded by the recess trench, and a second source/drain region disposed in a second active region of the active region, the second active region being disposed between the recess trench and the device isolation film, in a plan view, each of the buried electrode portion and the protruding electrode portion of the gate electrode is spaced apart from the device isolation film and is positioned entirely within the active region in the vertical direction, and each of the recess trench, the gate electrode, and the second source/drain region has a closed-loop shape in a plan view.

According to another aspect of the inventive concept, there is provided an integrated circuit device including a substrate having an active region defined by a device isolation film, a recess trench and a recess channel transistor. The recess trench is disposed in the active region and is spaced apart from the device isolation film. The recess trench extends in a vertical direction from a main surface of the substrate towards an interior of the substrate. The recess trench includes a first portion and a second portion, the second portion being positioned below the first portion and having a greater width than the first portion. The recess channel transistor includes a gate electrode disposed within the recess trench. The recess channel transistor includes a channel positioned along a surface of the recess trench. Each of the recess trench and the gate electrode has a closed-loop shape in a plan view, and where the gate electrode is arranged within the recess trench to correspond to the first and second portions of the recess trench.

### BRIEF DESCRIPTION OF THE DRAWINGS

Embodiments will be more clearly understood from the following detailed description taken in conjunction with the accompanying drawings in which:

FIG. 1A is a planar layout diagram illustrating an integrated circuit device according to an embodiment;

FIG. 1B is a cross-sectional view of the integrated circuit device of FIG. 1A, taken along a line X1-X1′ of FIG. 1A;

FIG. 2 is a cross-sectional view illustrating an integrated circuit device according to an embodiment;

FIG. 3 is a cross-sectional view illustrating an integrated circuit device according to an embodiment;

FIGS. 4, 5, and 6 are planar layout diagrams each illustrating an integrated circuit device according to some embodiments;

FIG. 7 is a planar layout diagram illustrating an integrated circuit device according to an embodiment;

FIG. 8A is a planar layout diagram illustrating an integrated circuit device according to an embodiment;

FIG. 8B is a cross-sectional view of the integrated circuit device of FIG. 8A, taken along a line X7-X7′ of FIG. 8A;

FIG. 9 is a planar layout diagram illustrating an integrated circuit device according to an embodiment;

FIG. 10 is a planar layout diagram illustrating an integrated circuit device according to an embodiment;

FIG. 11 is a schematic block diagram of a display device according to an embodiment; and

FIGS. 12A to 12G are cross-sectional views respectively illustrating a sequence of processes of a method of fabricating an integrated circuit device, according to an embodiment.

### DETAILED DESCRIPTION

Embodiments of the inventive concept relate to an integrated circuit (IC) device featuring a recess channel transistor designed to enhance performance while minimizing chip area. The transistor includes a recess trench formed in the active region of a substrate, spaced apart from the device isolation film, and extending vertically into the substrate. A gate electrode, positioned within the recess trench, has a closed-loop shape in a plan view, which helps enhance threshold voltage stability and suppresses unintended edge channels that can degrade performance. The design also incorporates source/drain regions and a gate dielectric film to ensure reliable transistor operation.

Additionally, some embodiments include a pocket well and a deep well of different conductivity types to provide enhanced electrical isolation and high-voltage operation. The gate electrode consists of a buried electrode portion within the recess trench and a protruding electrode portion extending above the substrate surface, optimizing gate control. By preventing overlap with the device isolation film, the design reduces leakage current, enhances transistor reliability, and enables efficient scaling for display driver ICs and other semiconductor applications.

Hereinafter, embodiments of the inventive concept will be described in detail with reference to the accompanying drawings. Like components are denoted by like reference numerals throughout the specification, and repeated descriptions thereof are omitted.

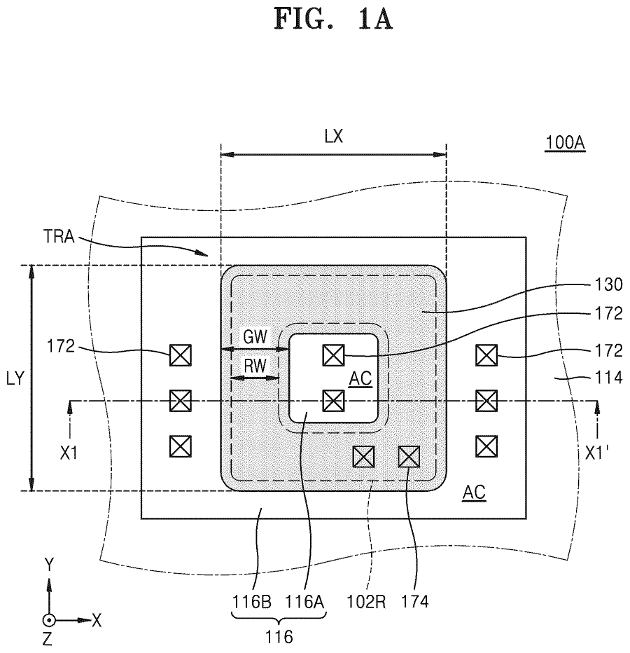

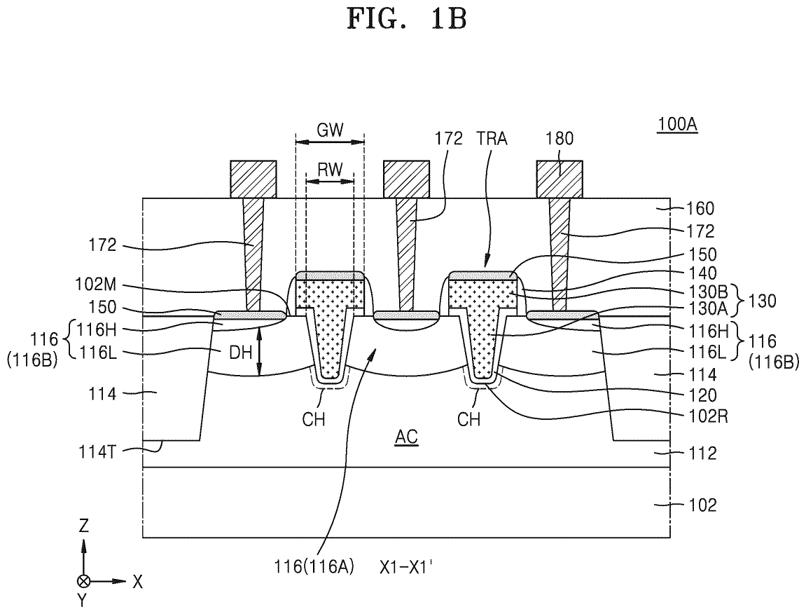

FIG. 1A is a planar layout diagram illustrating an integrated circuit device 100A according to an embodiment. FIG. 1B is a cross-sectional view of the integrated circuit device 100A, taken along line X1-X1′ of FIG. 1A.

Referring to FIGS. 1A and 1B, the integrated circuit device 100A may include a substrate 102 including a well 112, a device isolation film 114 buried in a portion of the substrate 102 in an area defined by the well 112, and an active region AC defined in the substrate 102 by the device isolation film 114. The device isolation film 114 may fill a trench region 114T formed in the substrate 102. The device isolation film 114 may include a silicon oxide film.

The substrate 102 may include a semiconductor substrate. In some embodiments, the substrate 102 may include a semiconductor, such as Silicon (Si) or Germanium (Ge). In some embodiments, the substrate 102 may include a compound semiconductor, such as Silicon-Germanium (SiGe), Silicon Carbide (SiC), Gallium Arsenide (GaAs), Indium Arsenide (InAs), or Indium Phosphide (InP).

A recess channel transistor TRA may be arranged on the active region AC. In some embodiments, the recess channel transistor TRA is a high-voltage transistor operated by a high power-supply voltage of about 8 V to about 200 V, but is not limited thereto.

A recess trench 102R may be arranged in the active region AC to be spaced apart from the device isolation film 114. In FIG. 1A, a planar shape of the recess trench 102R is shown by a dashed line. The recess trench 102R may include an inner space extending in a vertical direction (a Z direction) from a main surface 102M of the substrate 102 toward the inside of the substrate 102 or towards an interior of the substrate 102. The recess channel transistor TRA may be configured such that a channel thereof is formed or positioned along a surface of the recess trench 102R. The recess channel transistor TRA may include a channel region CH arranged in the well 112 to be adjacent to the bottom of the recess trench 102R.

In an embodiment, the recess channel transistor TRA includes a gate dielectric film 120, which covers an inner wall of the recess trench 102R, and a gate electrode 130 arranged on the gate dielectric film 120. The inner space of the recess trench 102R may be filled with the gate dielectric film 120 and the gate electrode 130. As shown in FIG. 1B, the gate electrode 130 may include a buried electrode portion 130A, which is arranged on the gate dielectric film 120 to fill the recess trench 102R, and a protruding electrode portion 130B, which is integrally connected to the buried electrode portion 130A and protrudes above the main surface 102M of the substrate 102. For example, the gate electrode 130 may include a buried electrode portion 130A, positioned on the gate dielectric film 120 and occupying the recess trench 102R, along with a protruding electrode portion 130B, which is seamlessly connected to the buried electrode portion 130A and extends above the main surface 102M of the substrate 102.

In an embodiment, the gate dielectric film 120 includes a silicon oxide film and the gate electrode 130 includes a doped polysilicon film. The doped polysilicon film constituting the gate electrode 130 may be doped with a p-type or n-type impurity according to a channel type of the recess channel transistor TRA. For example, when the recess channel transistor TRA includes a P-channel Metal-Oxide-Semiconductor (PMOS) transistor, the gate electrode 130 may include a polysilicon film doped with a p-type impurity, and when the recess channel transistor TRA includes a N-channel Metal-Oxide-Semiconductor (NMOS) transistor, the gate electrode 130 may include a polysilicon film doped with an n-type impurity.

The active region AC may include a local region (which may be referred to as a first active region) surrounded by the recess trench 102R, and a local region (which may be referred to as a second active region) arranged between the recess trench 102R and the device isolation film 114. The recess channel transistor TRA may include a plurality of source/drain regions 116 that are spaced apart from each other with the gate electrode 130 therebetween. The plurality of source/drain regions 116 may be arranged in the well 112.

As shown in FIG. 1A, the plurality of source/drain regions 116 may include a first source/drain region 116A and a second source/drain region 116B, which are apart from each other with the gate electrode 130 therebetween. The first source/drain region 116A may be arranged in the local region (the first active region), which is surrounded by the recess trench 102R in a plan view, of the active region AC. The second source/drain region 116B may be arranged in the local region (the second active region), which is between the recess trench 102R and the device isolation film 114 in a plan view, of the active region AC. In a plan view, the second source/drain region 116B may surround the first source/drain region 116A and the gate electrode 130. Herein, a plan view refers to a point of view from the X-Y plane, as shown in FIG. 1A. In the plurality of source/drain regions 116, when the first source/drain region 116A operates as a source, the second source/drain region 116B may operate as a drain. In the plurality of source/drain regions 116, when the first source/drain region 116A operates as a drain, the second source/drain region 116B may operate as a source.

The gate dielectric film 120 may include a first portion, which is disposed between the gate electrode 130 and each of the plurality of source/drain regions 116, and a second portion adjacent to the channel region CH. In an embodiments of the gate dielectric film 120, the thickness of the first portion is greater than the thickness of the second portion. In an embodiment, the gate dielectric film 120 covering the inner wall of the recess trench 102R covers the gate electrode 130 with a constant thickness, and thus, in the gate dielectric film 120, the thickness of the first portion may be substantially equal to the thickness of the second portion.

The integrated circuit device 100A may include an insulating spacer 140 covering sidewalls of the gate electrode 130. The insulating spacer 140 may include a portion vertically overlapping the plurality of source/drain regions 116. In some embodiments, the insulating spacer 140 may include a silicon oxide film, a silicon nitride film, or a combination thereof.

As shown in FIG. 1B, each of the plurality of source/drain regions 116 may include a lightly-doped region 116L and a heavily-doped region 116H that is self-aligned by the insulating spacer 140. For example, the heavily-doped region 116H may be formed in alignment with the edges of the insulating spacer 140, ensuring precise positioning relative to the gate structure. The heavily-doped region 116H may have an impurity concentration that is higher than the impurity concentration in the lightly-doped region 116L.

The well 112 may surround the plurality of source/drain regions 116. The well 112 may include an impurity-doped region of a first conductivity type, and the plurality of source/drain regions 116 may each include an impurity-doped region of a second conductivity type that is opposite to the first conductivity type. In some embodiments, the first conductivity type may be an n-type and the second conductivity type may be a p-type. In some embodiments, the first conductivity type may be a p-type and the second conductivity type may be an n-type.

As shown in FIG. 1A, in a plan view, each of the recess trench 102R and the gate electrode 130 may have a closed-loop shape. As used herein, the term “closed loop” refers to a structure in which a ring with an arbitrary shape continuously extends without breaking. In addition, the second source/drain region 116B disposed between the recess trench 102R and the device isolation film 114, among the plurality of source/drain regions 116, may have a closed-loop shape surrounding the recess trench 102R and the gate electrode 130, in a plan view.

In some embodiments, the gate electrode 130 may have a quadrangular closed-loop shape with rounded corners, in a plan view. For example, the gate electrode 130 may have a square closed-loop shape with rounded corners. In this case, in a plan view, a first length LX of the gate electrode 130 in a first horizontal direction (an X direction) may be equal to or substantially equal to a second length LY of the gate electrode 130 in a second horizontal direction (a Y direction) that is orthogonal to the first horizontal direction (the X direction). In some embodiments, the gate electrode 130 may have a rectangular closed-loop shape with rounded corners, in a plan view. In this case, in a plan view, the first length LX of the gate electrode 130 in the first horizontal direction (the X direction) may be different from the second length LY of the gate electrode 130 in the second horizontal direction (the Y direction) that is orthogonal to the first horizontal direction (the X direction).

As shown in FIGS. 1A and 1B, in a width direction of the gate electrode 130, according to an embodiment, a first width GW of the protruding electrode portion 130B of the gate electrode 130 is greater than a second width RW of the recess trench 102R. Herein, the width direction of the gate electrode 130 refers to a direction that is orthogonal to a length direction that is along a path of a closed loop including the gate electrode 130. When the first width GW of the protruding electrode portion 130B of the gate electrode 130 is greater than the second width RW of the recess trench 102R, the protruding electrode portion 130B of the gate electrode 130 may include a portion located outside the recess trench 102R to overlap the main surface 102M of the substrate 102 in the vertical direction (the Z direction). For example, if the first width GW of the protruding electrode portion 130B of the gate electrode 130 exceeds the second width RW of the recess trench 102R, a portion of the protruding electrode portion 130B may extend beyond the boundaries of the recess trench 102R, overlapping the main surface 102M of the substrate 102 in the vertical direction.

In a plan view, each of the buried electrode portion 130A and the protruding electrode portion 130B of the gate electrode 130 may be apart from the device isolation film 114 in a horizontal direction (for example, the X direction and the Y direction) with a sufficient distance therebetween not to overlap the device isolation film 114 in the vertical direction (the Z direction). For example, the buried electrode portion 130A and the protruding electrode portion 130B may remain entirely within the active region AC without extending over the device isolation film 114. As shown in FIGS. 1A and 1B, in the horizontal direction (for example, the X direction and the Y direction), the gate electrode 130 may be arranged to be sufficiently apart from the device isolation film 114 with the second source/drain region 116B therebetween, the second source/drain region 116B being one of the plurality of source/drain regions 116.

An upper surface of the gate electrode 130 and upper surfaces of the plurality of source/drain regions 116 may each be covered by a metal silicide film 150. In some embodiments, the metal silicide film 150 may include, but is not limited to, titanium (Ti) silicide, cobalt (Co) silicide, or nickel (Ni) silicide.

In an embodiment, the device isolation film 114 and the recess channel transistor TRA disposed on the substrate 102 are covered by an interlayer dielectric 160. The interlayer dielectric 160 may include an oxide film, a nitride film, or a combination thereof.

The integrated circuit device 100A may further include a plurality of source/drain contact plugs 172, which are connected to the heavily-doped regions 116H of the plurality of source/drain regions 116, and a plurality of gate contact plugs 174, which pass through the interlayer dielectric 160 and are connected to the gate electrode 130. Each of the plurality of source/drain contact plugs 172 may be connected to a heavily-doped region 116H of a source/drain region 116 via the metal silicide film 150. Each of the plurality of gate contact plugs 174 may be connected to the protruding electrode portion 130B of the gate electrode 130 via the metal silicide film 150. In some embodiments, the plurality of source/drain contact plugs 172 and the plurality of gate contact plugs 174 may each include a stack structure of a conductive barrier film and a metal plug. In the plurality of source/drain contact plugs 172 and the plurality of gate contact plugs 174, the conductive barrier film may include Ti, TiN, or a combination thereof and the metal plug may include tungsten (W), but the inventive concept is not limited thereto.

A plurality of wiring layers 180 may be arranged on the interlayer dielectric 160. The plurality of source/drain contact plugs 172 and the plurality of gate contact plugs 174 may each be connected to each one wiring layer 180 selected from the plurality of wiring layers 180. Each of the plurality of wiring layers 180 may include a stack structure of a conductive barrier film and a metal plug. In the plurality of wiring layers 180, the conductive barrier film may include Titanium (Ti), Titanium Nitride (TiN), or a combination thereof and the metal plug may include aluminum (Al), but the inventive concept is not limited thereto.

A high-voltage transistor may operate at a relatively high voltage. It may have a structure where the gate electrode is arranged adjacent to a device isolation film that defines an active region. Alternately, a portion of the gate electrode may extend over an upper surface of the device isolation film to overlap the device isolation film in a vertical direction. In such structures, a semiconductor fence may unintentionally form. This semiconductor fence, for example, a silicon fence, is a portion of the active region. The fence may appear between the gate electrode and the device isolation film, potentially affecting the device's performance. In this case, even when a voltage lower than a threshold voltage is applied to the gate electrode, channel inversion may easily occur in the vicinity of the silicon fence. As a result, an edge channel may be formed at a voltage lower than the threshold voltage in the vicinity of the silicon fence, thereby causing a hump phenomenon. When such a hump phenomenon occurs, it can lead to threshold voltage degradation in a transistor due to the formation of a parasitic transistor, an increase in leakage current at or below the threshold voltage, and inconsistent threshold voltage variations among transistors within the chip, potentially resulting in malfunctions.

In the recess channel transistor TRA of the integrated circuit device 100A described with reference to FIGS. 1A and 1B, by designing the buried electrode portion 130A, which fills the recess trench 102R, of the gate electrode 130 to have a sufficiently great length in the vertical direction (the Z direction), the channel length of the recess channel transistor TRA may be increased, thereby reducing an off-current. In addition, in the integrated circuit device 100A, by designing the buried electrode portion 130A, which fills the recess trench 102R, of the gate electrode 130 to have a sufficiently great length in the vertical direction (the Z direction), because a vertical-direction (Z-direction) length DH of the lightly-doped region 116L of the source/drain region 116 may be sufficiently secured, a sufficient depletion region may be secured in the recess channel transistor TRA. Thus, a voltage-resistant effect of the recess channel transistor TRA may be maximized.

Furthermore, the recess channel transistor TRA includes the gate electrode 130 arranged in the active region AC to be sufficiently spaced apart from the device isolation film 114 with the second source/drain region 116B disposed therebetween, the second source/drain region 116B being one of the plurality of source/drain regions 116, and the gate electrode 130 has a closed-loop shape in a plan view. Therefore, according to the integrated circuit device 100A of the inventive concept, an occupied area of a high-voltage transistor including the recess channel transistor TRA may be reduced, and a hump phenomenon due to the formation of an unintended edge channel in the recess channel transistor TRA may be prevented. In addition, the integrated circuit device 100A may have a structure that effectively reduces threshold voltage variations among transistors in a chip, and increases the effective gate length of the recess channel transistor TRA. Therefore, the integrated circuit device 100A according to the inventive concept may achieve the intended performance with a minimum area in a reduced area and may provide excellent reliability.

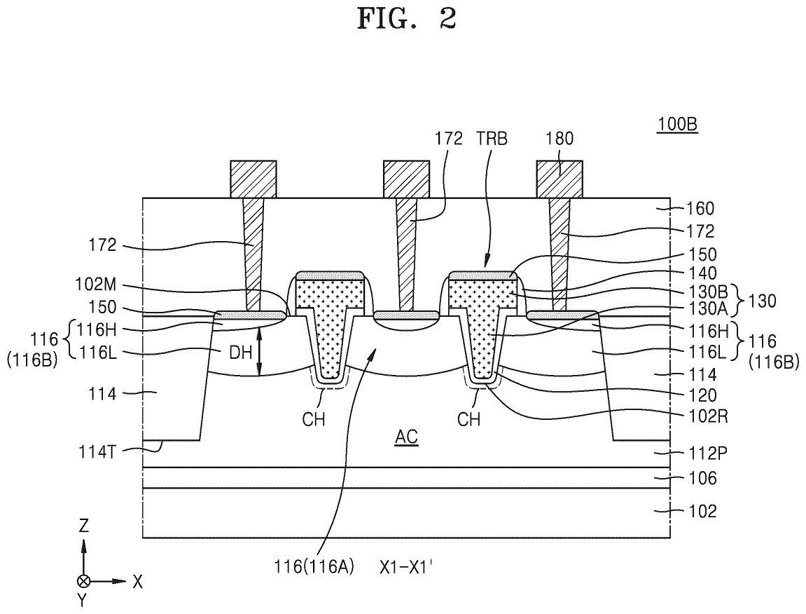

FIG. 2 is a cross-sectional view illustrating an integrated circuit device 100B according to an embodiment. FIG. 2 illustrates a cross-sectional configuration of a portion of the integrated circuit device 100B, the portion corresponding to the cross-section taken along the line X1-X1′ of FIG. 1A. In FIG. 2, the same reference numerals as in FIGS. 1A and 1B respectively denote the same members, and here, repeated descriptions thereof are omitted.

Referring to FIG. 2, the integrated circuit device 100B has substantially the same configuration as the integrated circuit device 100A shown in FIGS. 1A and 1B. However, the integrated circuit device 100B includes a recess channel transistor TRB having a triple well structure. The integrated circuit device 100B includes a pocket well 112P of a first conductivity type, which accommodates the recess trench 102R constituting the recess channel transistor TRB, and a deep well 106 of a second conductivity type, which accommodates the pocket well 112P. The triple well includes: the pocket well 112P providing local doping control for the transistor; the deep well 106 serving as isolation from the substrate 102; and the substrate 102 itself acting as the third well region to ensure enhanced isolation and reduced noise coupling.

In an embodiment, the recess channel transistor TRB includes a gate dielectric film 120 covering the inner wall of the recess trench 102R, a plurality of source/drain regions 116 arranged in the pocket well 112P, and a channel region CH arranged in the pocket well 112P to be adjacent to the bottom of the recess trench 102R. In the recess channel transistor TRB, the plurality of source/drain regions 116 may include a first source/drain region 116A arranged in a local region (which may be referred to as a first active region), which is surrounded by the recess trench 102R in a plan view, of the active region AC, and a second source/drain region 116B arranged in a local region (which may be referred to as a second active region), which is between the recess trench 102R and the device isolation film 114 in a plan view, of the active region AC. A more detailed configuration of the recess channel transistor TRB is substantially the same as that of the recess channel transistor TRA described with reference to FIGS. 1A and 1B.

When the recess channel transistor TRB includes an NMOS transistor, each of the deep well 106 and the plurality of source/drain regions 116 may include an impurity region doped with an N-type impurity, and the pocket well 112P may include an impurity region doped with a P-type impurity. When the recess channel transistor TRB includes a PMOS transistor, each of the deep well 106 and the plurality of source/drain regions 116 may include an impurity region doped with a P-type impurity, and the pocket well 112P may include an impurity region doped with an N-type impurity.

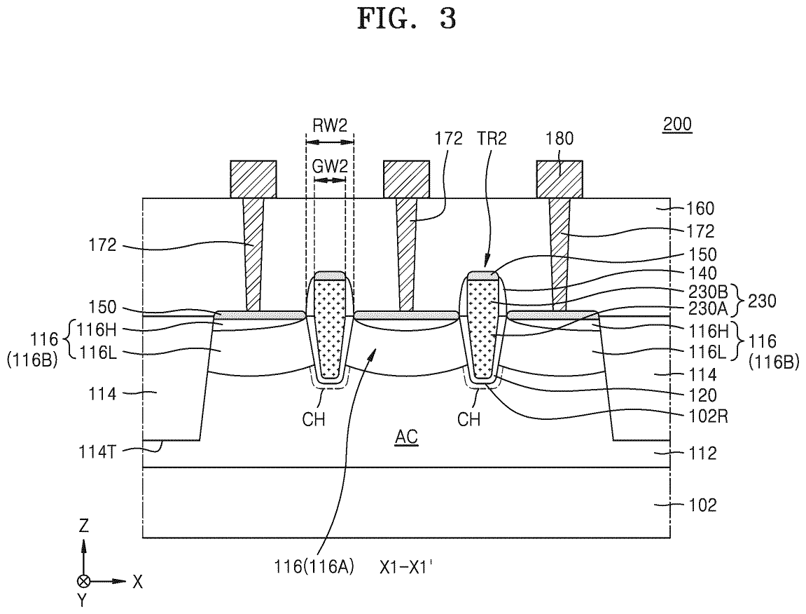

FIG. 3 is a cross-sectional view illustrating an integrated circuit device 200 according to an embodiment. FIG. 3 illustrates a cross-sectional configuration of a portion of the integrated circuit device 200, the portion corresponding to the cross-section taken along the line X1-X1′ of FIG. 1A. In FIG. 3, the same reference numerals as in FIGS. 1A and 1B respectively denote the same members, and here, repeated descriptions thereof are omitted.

Referring to FIG. 3, the integrated circuit device 200 has substantially the same configuration as the integrated circuit device 100A shown in FIGS. 1A and 1B. However, a recess channel transistor TR2 of the integrated circuit device 200 includes a gate electrode 230. Similar to the gate electrode 130 described with reference to FIGS. 1A and 1B, the gate electrode 230 may have a closed-loop shape in a plan view.

In an embodiment, the gate electrode 230 includes a buried electrode portion 230A, which is arranged on the gate dielectric film 120 to fill the recess trench 102R, and a protruding electrode portion 230B, which is integrally connected to the buried electrode portion 230A and protrudes above the main surface 102M of the substrate 102. In a plan view, each of the buried electrode portion 230A and the protruding electrode portion 230B of the gate electrode 230 may be apart from the device isolation film 114 in the horizontal direction with a sufficient distance therebetween not to overlap the device isolation film 114 in the vertical direction (the Z direction). For example, as shown in FIG. 3, in the first horizontal direction (the X direction), each of the buried electrode portion 230A and the protruding electrode portion 230B of the gate electrode 230 may be arranged to be sufficiently apart from the device isolation film 114 in the horizontal direction with the second source/drain region 116B therebetween, the second source/drain region 116B being one of the plurality of source/drain regions 116.

In a width direction of the gate electrode 230, according to an embodiment, a first width GW2 of the protruding electrode portion 230B of the gate electrode 230 is less than a second width RW2 of the recess trench 102R. A more detailed configuration of the gate electrode 230 is substantially similar to that of the gate electrode 130 described with reference to FIGS. 1A and 1B.

In the integrated circuit device 200, the protruding electrode portion 230B of the gate electrode 230 of the recess channel transistor TR2 may have a relatively small width, whereby the area occupied by the recess channel transistor TR2 in the integrated circuit device 200 may be further reduced.

For example, the primary difference between FIG. 3 and FIG. 1 is that FIG. 3 features a narrower gate electrode, making the transistor more compact and potentially increasing integration, whereas FIGS. 1A and 1B has a wider gate electrode, offering stronger gate control but occupying more space.

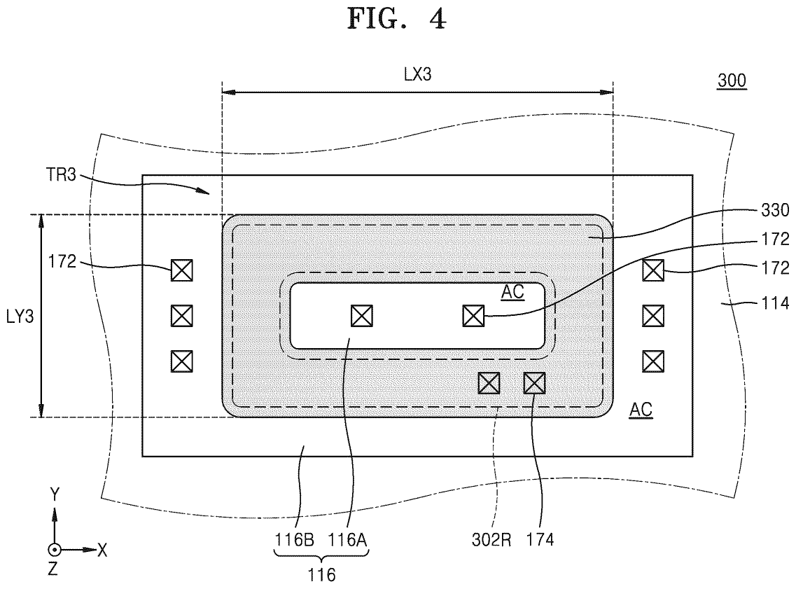

FIGS. 4, 5, and 6 are planar layout diagrams respectively illustrating integrated circuit devices 300, 400, and 500 according to some embodiments. In FIGS. 4, 5, and 6, the same reference numerals as in FIGS. 1A and 1B respectively denote the same members, and here, repeated descriptions thereof are omitted.

Referring to FIG. 4, the integrated circuit device 300 includes a recess channel transistor TR3. The recess channel transistor TR3 has substantially the same configuration as the recess channel transistor TRA described with reference to FIGS. 1A and 1B. However, the recess channel transistor TR3 of the integrated circuit device 300 includes a gate electrode 330. The gate electrode 330 of the recess channel transistor TR3, and a recess trench 302R accommodating a portion of the gate electrode 330 may each have a rectangular closed-loop shape with rounded corners, in a plan view. In a plan view, a first length LX3 of the gate electrode 330 in the first horizontal direction (the X direction) may be different from a second length LY3 of the gate electrode 330 in the second horizontal direction (the Y direction) that is orthogonal to the first horizontal direction (the X direction). FIG. 4 illustrates an example in which the first length LX3 of the gate electrode 330 in the first horizontal direction (the X direction) is greater than the second length LY3 of the gate electrode 330 in the second horizontal direction (the Y direction). However, the inventive concept is not limited to the example shown in FIG. 4. For example, the second length LY3 of the gate electrode 330 in the second horizontal direction (the Y direction) may be greater than the first length LX3 of the gate electrode 330 in the first horizontal direction (the X direction).

FIG. 4 differs from FIGS. 1A and 1B primarily in the plan-view shape of the gate electrode and recess trench. FIGS. 1A and 1B has a quadrangular (square-like) shape, while FIG. 4 features a rectangular shape elongated in one direction, which may be used to optimize the transistor's performance characteristics or adapt to layout constraints.

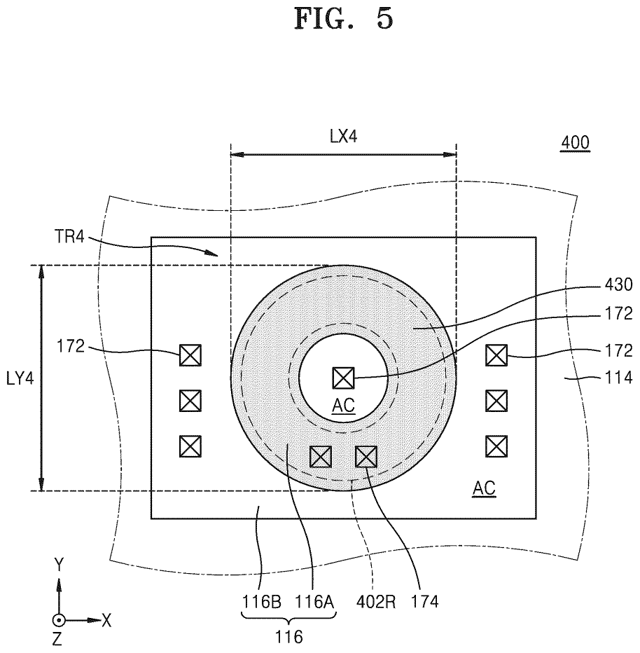

Referring to FIG. 5, the integrated circuit device 400 includes a recess channel transistor TR4. The recess channel transistor TR4 has substantially the same configuration as the recess channel transistor TRA described with reference to FIGS. 1A and 1B. However, the recess channel transistor TR4 of the integrated circuit device 400 includes a gate electrode 430. In an embodiment, the gate electrode 430 of the recess channel transistor TR4, and a recess trench 402R accommodating a portion of the gate electrode 430 each have a circular closed-loop shape in a plan view. In a plan view, a first length LX4 of the gate electrode 430 in the first horizontal direction (the X direction) may be equal to or substantially equal to a second length LY4 of the gate electrode 430 in the second horizontal direction (the Y direction) that is orthogonal to the first horizontal direction (the X direction).

FIG. 5 differs from FIGS. 1A and 1B primarily in the shape of the gate electrode and recess trench. While FIGS. 1A and 1B has a quadrangular shape, FIG. 5 features a circular closed-loop shape, which may help enhance threshold voltage stability and reduce electric field concentration at edges, enhancing transistor reliability.

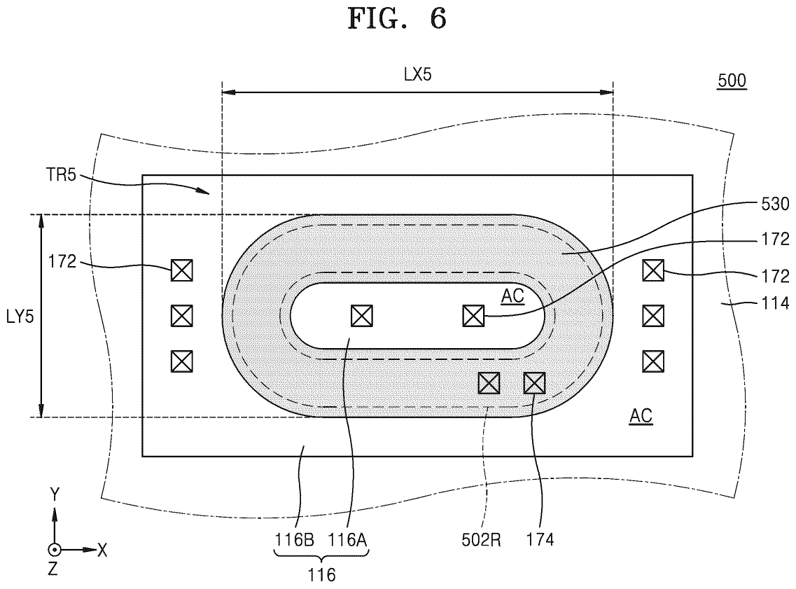

Referring to FIG. 6, the integrated circuit device 500 includes a recess channel transistor TR5. The recess channel transistor TR5 has substantially the same configuration as the recess channel transistor TRA described with reference to FIGS. 1A and 1B. However, the recess channel transistor TR5 of the integrated circuit device 500 includes a gate electrode 530. In an embodiment, the gate electrode 530 of the recess channel transistor TR5, and a recess trench 502R accommodating a portion of the gate electrode 530 each have an elliptical closed-loop shape in a plan view. In a plan view, a first length LX5 of the gate electrode 530 in the first horizontal direction (the X direction) may be different from a second length LY5 of the gate electrode 530 in the second horizontal direction (the Y direction) that is orthogonal to the first horizontal direction (the X direction). FIG. 6 illustrates an example in which the first length LX5 of the gate electrode 530 in the first horizontal direction (the X direction) is greater than the second length LY5 of the gate electrode 530 in the second horizontal direction (the Y direction). However, the inventive concept is not limited to the example shown in FIG. 6. For example, the second length LY5 of the gate electrode 530 in the second horizontal direction (the Y direction) may be greater than the first length LX5 of the gate electrode 530 in the first horizontal direction (the X direction).

FIG. 6 differs from FIGS. 1A and 1B primarily in the shape of the gate electrode and recess trench. While FIGS. 1A and 1B has a quadrangular shape, FIG. 6 features an elliptical closed-loop shape, which may provide benefits in terms of current directionality and electric field distribution, potentially enhancing certain performance characteristics of the transistor.

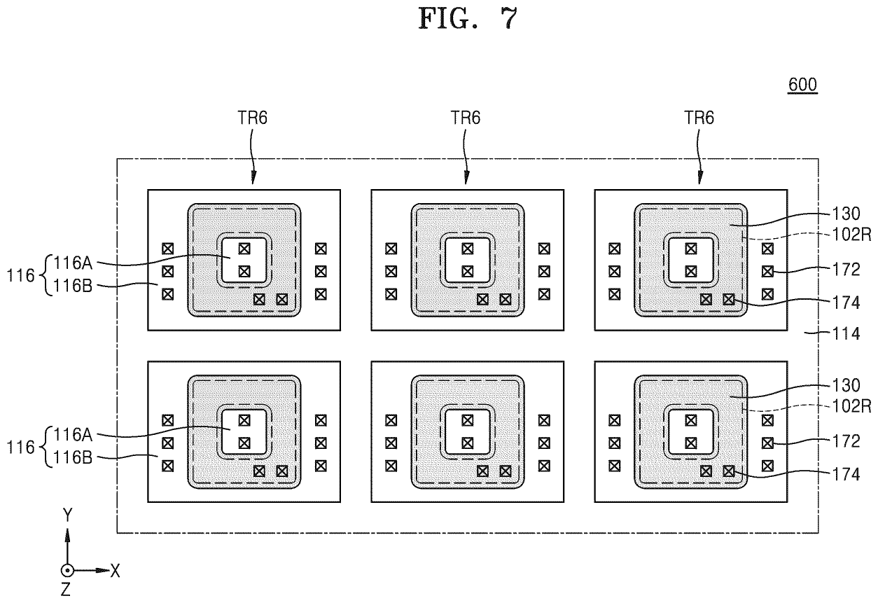

FIG. 7 is a planar layout diagram illustrating an integrated circuit device 600 according to an embodiment. In FIG. 7, the same reference numerals as in FIGS. 1A and 1B respectively denote the same members, and here, repeated descriptions thereof are omitted.

Referring to FIG. 7, the integrated circuit device 600 includes a plurality of recess channel transistors TR6. Each of the plurality of recess channel transistors TR6 may have substantially the same configuration as the recess channel transistor TRA described with reference to FIGS. 1A and 1B.

In the integrated circuit device 600, the plurality of recess channel transistors TR6 may be arranged apart from each other with the device isolation film 114 therebetween. At least some of the plurality of recess channel transistors TR6 may be connected to each other in series or in parallel.

Although FIG. 7 illustrates an example where a plurality of recess channel transistors TR6 are arranged in a matrix configuration, with three recess channel transistors TR6 aligned in a row along the first horizontal direction (the X direction) and two recess channel transistors TR6 aligned in a row along the second horizontal direction (the Y direction), the inventive concept is not limited thereto. In the plurality of recess channel transistors TR6, the respective numbers of recess channel transistors TR6 arranged in the first horizontal direction (the X direction) and the second horizontal direction (the Y direction), and the overall arrangement structure of the recess channel transistors TR6 may be variously modified as needed.

Although FIG. 7 illustrates an example in which each of the plurality of recess channel transistors TR6 of the integrated circuit device 600 has the same configuration as the recess channel transistor TRA described with reference to FIGS. 1A and 1B, the inventive concept is not limited thereto. For example, in the integrated circuit device 600, the recess channel transistor TRB, TR2, TR3, TR4, or TR5 shown in FIGS. 2 to 6, recess channel transistors having various structures changed and modified from the recess channel transistor TRB, TR2, TR3, TR4, or TR5 without departing from the scope of the inventive concept, or recess channel transistors including combinations thereof may be used instead of the plurality of recess channel transistors TR6.

FIG. 7 differs from FIGS. 1A and 1B primarily by featuring multiple recess channel transistors arranged in an array, whereas FIGS. 1A and 1B depicts a single transistor. This difference enables scalability, higher current handling, and integrated circuit flexibility, making FIG. 7 suitable for applications requiring multiple transistors working together in a structured layout.

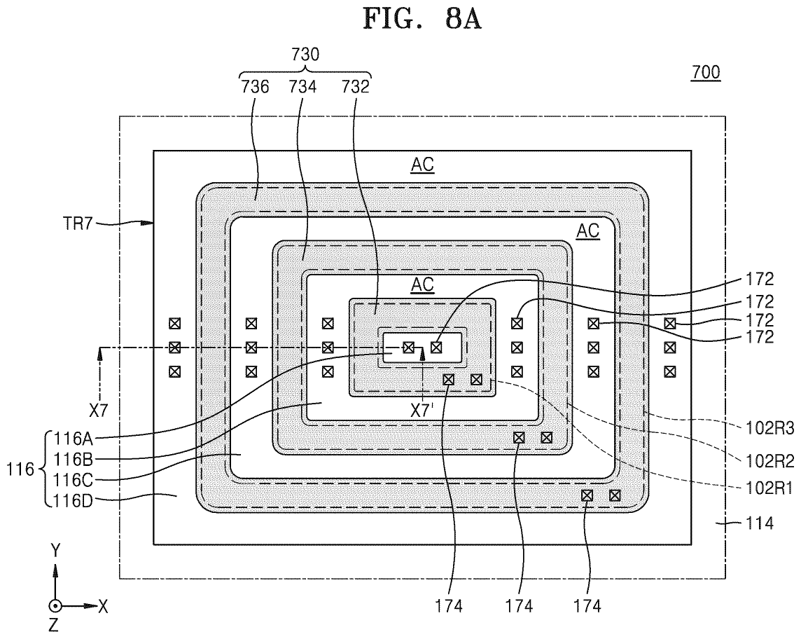

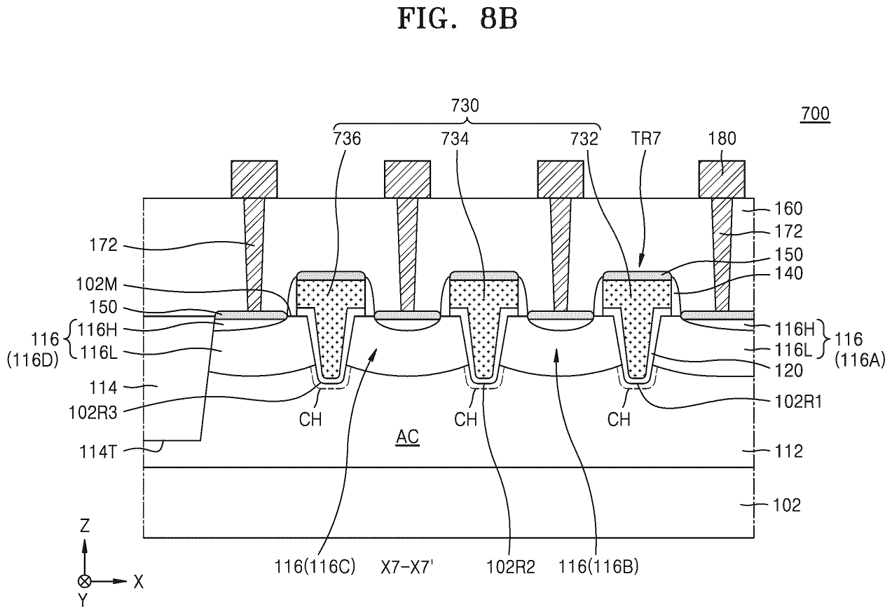

FIG. 8A is a planar layout diagram illustrating an integrated circuit device 700 according to an embodiment. FIG. 8B is a cross-sectional view of the integrated circuit device 700, taken along a line X7-X7′ of FIG. 8A. In FIGS. 8A and 8B, the same reference numerals as in FIGS. 1A and 1B respectively denote the same members, and here, repeated descriptions thereof are omitted.

Referring to FIGS. 8A and 8B, the integrated circuit device 700 includes a recess channel transistor TR7. The recess channel transistor TR7 may include components similar to those of the recess channel transistor TRA described with reference to FIGS. 1A and 1B. However, the recess channel transistor TR7 includes a plurality of recess trenches, a plurality of gate electrodes 730 respectively filling the plurality of recess trenches, and a plurality of source/drain regions 116. The plurality of recess trenches includes a first recess trench 102R1, a second recess trench 102R2, and a third recess trench 102R3. The plurality of gate electrodes 730 include a first gate electrode 732 filling the first recess trench 102R1, a second gate electrode 734 filling the second recess trench 102R2, and a third gate electrode 736 filling the third recess trench 102R3.

The plurality of source/drain regions 116 include first to fourth source/drain regions 116A, 116B, 116C, and 116D. In a plan view, the first source/drain region 116A may be arranged in a local region (which may be referred to as a first active region) surrounded by the first recess trench 102R1 and may be surrounded by the first gate electrode 732. In a plan view, the second source/drain region 116B may be arranged in a local region (which may be referred to as a second active region) between the first recess trench 102R1 and the second recess trench 102R2. The second source/drain region 116B may be arranged between the first gate electrode 732 and the second gate electrode 734 and may be surrounded by the second gate electrode 734. In a plan view, the third source/drain region 116C may be arranged in a local region (which may be referred to as a third active region) between the second recess trench 102R2 and the third recess trench 102R3. The third source/drain region 116C may be arranged between the second gate electrode 734 and the third gate electrode 736 and may be surrounded by the third gate electrode 736. In a plan view, the fourth source/drain region 116D may be arranged in a local region (which may be referred to as a fourth active region) between the third recess trench 102R3 and the device isolation film 114. The fourth source/drain region 116D may be arranged between the third gate electrode 736 and the device isolation film 114 and may be surrounded by the device isolation film 114.

An upper surface of each of the plurality of source/drain regions 116 and the plurality of gate electrodes 730 may be covered by a metal silicide film 150. Each of the plurality of source/drain regions 116 may be connected to at least one source/drain contact plug 172 via the metal silicide film 150. Each of the plurality of gate electrodes 730 may be connected to at least one gate contact plug 174 via the metal silicide film 150.

The first recess trench 102R1 is located apart from the device isolation film 114 and extends in the vertical direction (the Z direction) from the main surface 102M of the substrate 102 toward the inside of the substrate 102. The second recess trench 102R2 is arranged in the active region AC between the device isolation film 114 and the first recess trench 102R1 to be apart from the device isolation film 114 and extends in the vertical direction (the Z direction) from the main surface 102M of the substrate 102 toward the inside of the substrate 102. The third recess trench 102R3 is arranged in the active region AC between the device isolation film 114 and the second recess trench 102R2 to be apart from the device isolation film 114 and extends in the vertical direction (the Z direction) from the main surface 102M of the substrate 102 toward the inside of the substrate 102.

In the integrated circuit device 700, the plurality of recess trenches including the first recess trench 102R1, the second recess trench 102R2, and the third recess trench 102R3, and the plurality of gate electrodes 730 including the first to third gate electrodes 732, 734, and 736 each have a quadrangular closed-loop shape with rounded corners, in a plan view. In a plan view, the second recess trench 102R2 may be arranged apart from the first recess trench 102R1 and may surround the first recess trench 102R1, and the third recess trench 102R3 may be arranged apart from the second recess trench 102R2 and may surround the first recess trench 102R1 and the second recess trench 102R2. In a plan view, the second gate electrode 734 may surround the first gate electrode 732, and the third gate electrode 736 may surround the first gate electrode 732 and the second gate electrode 734.

In a plan view, the second to fourth source/drain regions 116B, 116C, and 116D from among the first to fourth source/drain regions 116A, 116B, 116C, and 116D of the plurality of source/drain regions 116 each have a closed-loop shape. The third gate electrode 736 closest to the device isolation film 114 and located at the outermost position, among the plurality of gate electrodes 730 in the recess channel transistor TR7, may be arranged to be sufficiently apart from the device isolation film 114 in the horizontal direction with the fourth source/drain region 116D therebetween, the fourth source/drain region 116D being closest to the device isolation film 114 among the plurality of source/drain regions 116 in the recess channel transistor TR7.

A more detailed configuration of each of the first recess trench 102R1, the second recess trench 102R2, and the third recess trench 102R3, which constitute the recess channel transistor TR7, is substantially the same as that of the recess trench 102R described with reference to FIGS. 1A and 1B. A more detailed configuration of each of the plurality of gate electrodes 730 in the recess channel transistor TR7 is substantially the same as that of the gate electrode 130 described with reference to FIGS. 1A and 1B. A more detailed configuration of each of the first to fourth source/drain regions 116A, 116B, 116C, and 116D in the recess channel transistor TR7 is substantially the same as that of the source/drain region 116 described with reference to FIGS. 1A and 1B. In some embodiments, in the recess channel transistor TR7 shown in FIGS. 8A and 8B, the third recess trench 102R3, the third gate electrode 736, and the fourth source/drain region 116D may be omitted.

FIGS. 8A 8B differ from FIGS. 1A and 1B by featuring a recess trench with a variable depth, whereas FIGS. 1A and 1B uses a fixed-depth trench. This design modification may help optimize electric field characteristics, threshold voltage stability, and carrier mobility, making the structure of FIGS. 8A and 8B potentially more efficient for certain high-performance applications.

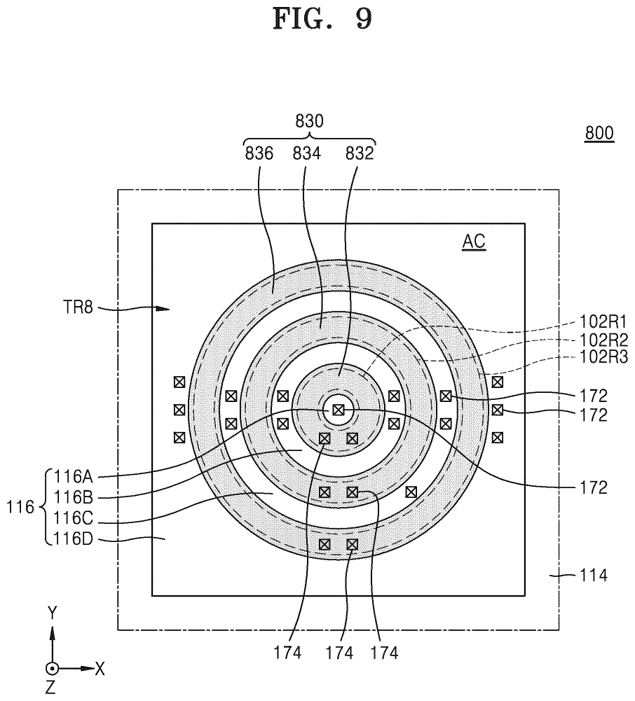

FIG. 9 is a planar layout diagram illustrating an integrated circuit device 800 according to an embodiment. In FIG. 9, the same reference numerals as in FIGS. 1A, 1B, 8A, and 8B respectively denote the same members, and here, repeated descriptions thereof are omitted.

Referring to FIG. 9, the integrated circuit device 800 includes a recess channel transistor TR8. The recess channel transistor TR8 may include components similar to those of the recess channel transistor TR7 described with reference to FIGS. 8A and 8B. However, the recess channel transistor TR8 includes a plurality of recess trenches including a first recess trench 102R1, a second recess trench 102R2, and a third recess trench 102R3, and a plurality of gate electrodes 830 respectively filling the plurality of recess trenches. The plurality of gate electrodes 830 include a first gate electrode 832 filling the first recess trench 102R1, a second gate electrode 834 filling the second recess trench 102R2, and a third gate electrode 836 filling the third recess trench 102R3.

The first source/drain region 116A may be surrounded by the first gate electrode 832. The second source/drain region 116B may be arranged between the first gate electrode 832 and the second gate electrode 834 and may be surrounded by the second gate electrode 834. The third source/drain region 116C may be arranged between the second gate electrode 834 and the third gate electrode 836 and may be surrounded by the third gate electrode 836. The fourth source/drain region 116D may be arranged between the third gate electrode 836 and the device isolation film 114 and may be surrounded by the device isolation film 114.

In the integrated circuit device 800, the plurality of recess trenches including the first recess trench 102R1, the second recess trench 102R2, and the third recess trench 102R3, and the plurality of gate electrodes 830 including the first to third gate electrodes 832, 834, and 836 each have a circular closed-loop shape. In a plan view, the second gate electrode 834 may surround the first gate electrode 832, and the third gate electrode 836 may surround the first gate electrode 832 and the second gate electrode 834.

The third gate electrode 836 closest to the device isolation film 114 and located at the outermost position, among the plurality of gate electrodes 830 in the recess channel transistor TR8, may be arranged to be sufficiently apart from the device isolation film 114 in the horizontal direction with the fourth source/drain region 116D therebetween, the fourth source/drain region 116D being closest to the device isolation film 114 among the plurality of source/drain regions 116 in the recess channel transistor TR8.

A more detailed configuration of each of the plurality of gate electrodes 830 in the recess channel transistor TR8 is substantially the same as that of the gate electrode 130 described with reference to FIGS. 1A and 1B. In some embodiments, in the recess channel transistor TR8, the third recess trench 102R3, the third gate electrode 836, and the fourth source/drain region 116D may be omitted.

FIG. 9 differs from FIGS. 8A and 8B in that it features a stepped-depth recess trench, whereas FIGS. 8A and 8B has a variable-depth trench. The stepped-depth trench in FIG. 9 allows for precise electric field and charge control at different depths, which may be useful for reducing leakage current, enhancing carrier mobility, and fine-tuning transistor performance.

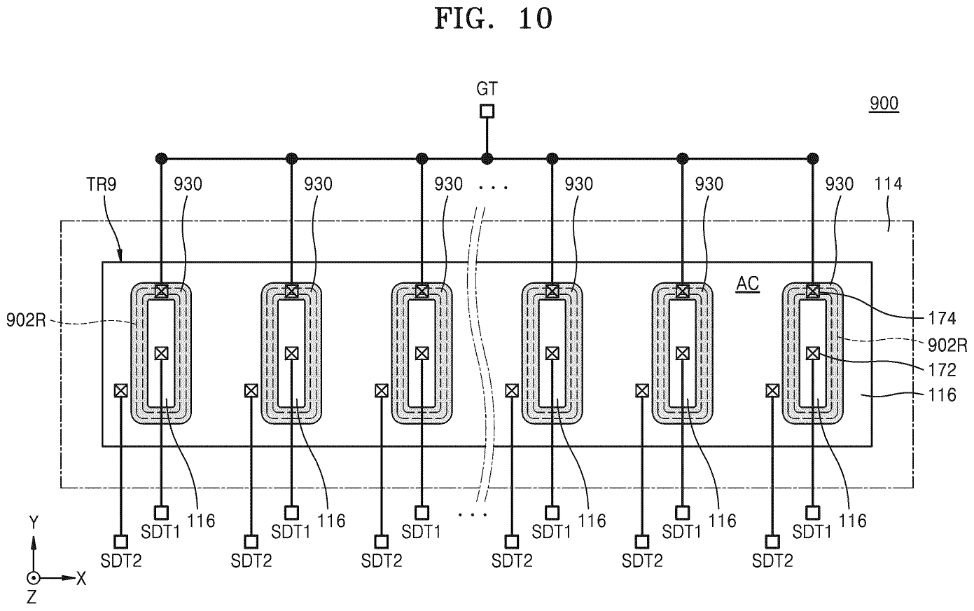

FIG. 10 is a planar layout diagram illustrating an integrated circuit device 900 according to an embodiment. In FIG. 10, the same reference numerals as in FIGS. 1A and 1B respectively denote the same members, and here, repeated descriptions thereof are omitted.

Referring to FIG. 10, the integrated circuit device 900 includes a recess channel transistor TR9. The recess channel transistor TR9 may include components similar to those of the recess channel transistor TRA described with reference to FIGS. 1A and 1B.

More specifically, the recess channel transistor TR9 includes a plurality of recess trenches 902R arranged in one active region AC, a plurality of gate electrodes 930 arranged on the one active region AC to respectively fill the plurality of recess trenches 902R, and a plurality of source/drain regions 116. The recess channel transistor TR9 may include an NMOS transistor or a PMOS transistor.

Each of the plurality of recess trenches 902R may have substantially the same configuration as the recess trench 102R described with reference to FIGS. 1A and 1B. Each of the plurality of gate electrodes 930 may have substantially the same configuration as the gate electrode 130 described with reference to FIGS. 1A and 1B.

As described with reference to FIG. 1B, each of the plurality of source/drain regions 116 may include a lightly-doped region 116L and a heavily-doped region 116H. In a plan view, the outermost source/drain region 116 closest to the device isolation film 114, among the plurality of source/drain regions 116, may surround all the plurality of gate electrodes 930 arranged on one active region AC. Other source/drain regions 116 except for the outermost source/drain region 116 among the plurality of source/drain regions 116 may each be surrounded by each one recess trench 902R and each one gate electrode 930.

The plurality of recess trenches 902R and the plurality of gate electrodes 930 each have a closed-loop shape in a plan view. Although FIG. 10 illustrates an example in which each of the plurality of recess trenches 902R and the plurality of gate electrodes 930 has a quadrangular closed-loop shape with rounded corners, the inventive concept is not limited thereto. For example, each of the plurality of recess trenches 902R and the plurality of gate electrodes 930 may have an elliptical or circular closed-loop shape in a plan view.

Similar to the gate electrode 130 described with reference to FIGS. 1A and 1B, a portion of each of the plurality of gate electrodes 930 may be accommodated in the recess trench 902R. The plurality of recess trenches 902R may be arranged apart from each other in one active region AC, and thus, the plurality of gate electrodes 930 may also be arranged apart from each other in the one active region AC.

In a plan view, each of the plurality of gate electrodes 930 may be arranged to be sufficiently apart from the device isolation film 114 in the horizontal direction (for example, the X direction and the Y direction). Each of the plurality of gate electrodes 930 may be arranged to be sufficiently apart from the device isolation film 114 in the horizontal direction with the outermost source/drain region 116 from among the plurality of source/drain regions 116 therebetween.

The plurality of gate contact plugs 174 respectively connected to the plurality of gate electrodes 930 may be connected to each other via a common gate terminal GT, and the plurality of gate electrodes 930 may be connected to each other in parallel. Source/drain regions 116 respectively surrounded by the plurality of gate electrodes 930, among the plurality of source/drain regions 116, may each be connected to a first source/drain terminal SDT1 via a source/drain contact plug 172, and the outermost source/drain region 116 surrounding the plurality of gate electrodes 930, among the plurality of source/drain regions 116, may be connected to a second source/drain terminal SDT2 via the source/drain contact plug 172.

The recess channel transistor TR9 in the integrated circuit device 900 may constitute a multi-finger transistor. In the recess channel transistor TR9, a channel width may be determined to be a value obtained by multiplying the number of gate electrodes 930 by a channel width obtained from one gate electrode 930. Therefore, the transconductance in the recess channel transistor TR9 may be increased, thereby enhancing the performance of the recess channel transistor TR9.

Similar to the integrated circuit device 100A described with reference to FIGS. 1A and 1B, according to the integrated circuit devices 100B, 200, 300, 400, 500, 600, 700, 800, and 900 described with reference to FIGS. 2 to 10, an off-current may be reduced by an increase in a channel length of a recess channel transistor, and a voltage-resistant effect of the recess channel transistor may be maximized. In addition, a gate electrode of each of recess channel transistors, which are included in the integrated circuit devices 100B, 200, 300, 400, 500, 600, 700, 800, and 900, is arranged in an active region to be sufficiently apart from a device isolation film with a source/drain region therebetween and has a closed-loop shape in a plan view. Therefore, an occupied area of a high-voltage transistor including the recess channel transistor may be reduced, and a hump phenomenon due to the formation of an unintended edge channel in the recess channel transistor may be prevented. In addition, the recess channel transistor in each of the integrated circuit devices 100B, 200, 300, 400, 500, 600, 700, 800, and 900 may be structured to effectively reduce threshold voltage variations among transistors in a chip while increasing its effective gate length. Therefore, each of the integrated circuit devices 100B, 200, 300, 400, 500, 600, 700, 800, and 900 according to the inventive concept may achieve intended performance with a minimum area in a reduced area and may provide excellent reliability.

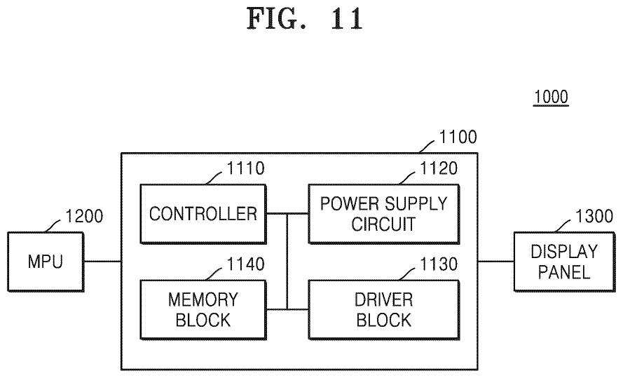

FIG. 11 is a schematic block diagram of a display device 1000 according to an embodiment.

Referring to FIG. 11, the display device 1000 includes a display driver integrated circuit (DDI) 1100. The DDI 1100 may include a controller 1110 (e.g., a controller circuit), a power supply circuit 1120, a driver block 1130 (e.g., a driver circuit), and a memory block 1140 (e.g., a memory device). The controller 1110 may receive and decode a command applied by a main processing unit (MPU) 1200 and may control respective blocks of the DDI 1100 to implement an operation according to the command. The power supply circuit 1120 may generate a driving voltage in response to control by the controller 1110. The driver block 1130 may drive a display panel 1300 by using the driving voltage generated by the power supply circuit 1120, in response to control by the controller 1110. The display panel 1300 may include a liquid-crystal display panel or a plasma display panel. The memory block 1140 may temporarily store commands input to the controller 1110 or control signals output from the controller 1110 or may store required data. The memory block 1140 may include memory, such as random-access memory (RAM) or read-only memory (ROM). Each of the power supply circuit 1120 and the driver block 1130 may include at least one of the recess channel transistors TRA, TRB, TR2, TR3, TR4, TR5, TR6, TR7, TR8, and TR9, which are respectively included in the integrated circuit devices 100A, 100B, 200, 300, 400, 500, 600, 700, 800, and 900 described with reference to FIGS. 1A to 10. Each of the controller 1110 and the memory block 1140 may further include a low-voltage transistor operating at a lower voltage than the recess channel transistors TRA, TRB, TR2, TR3, TR4, TR5, TR6, TR7, TR8, and TR9, which are respectively included in the integrated circuit devices 100A, 100B, 200, 300, 400, 500, 600, 700, 800, and 900.

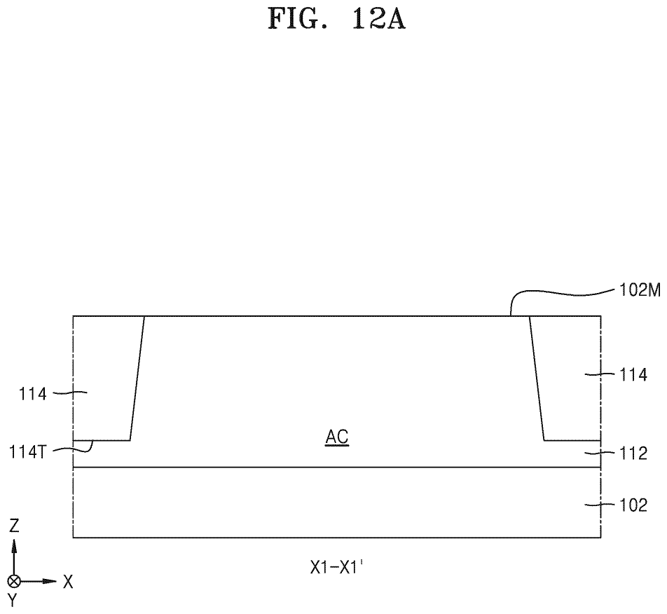

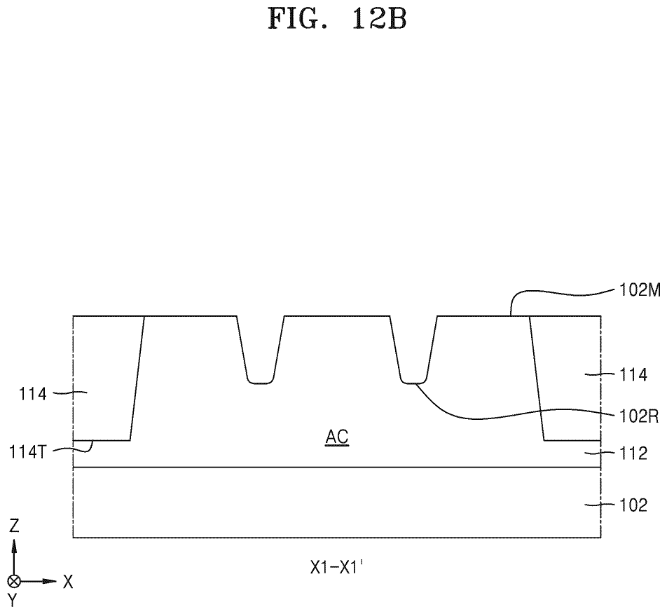

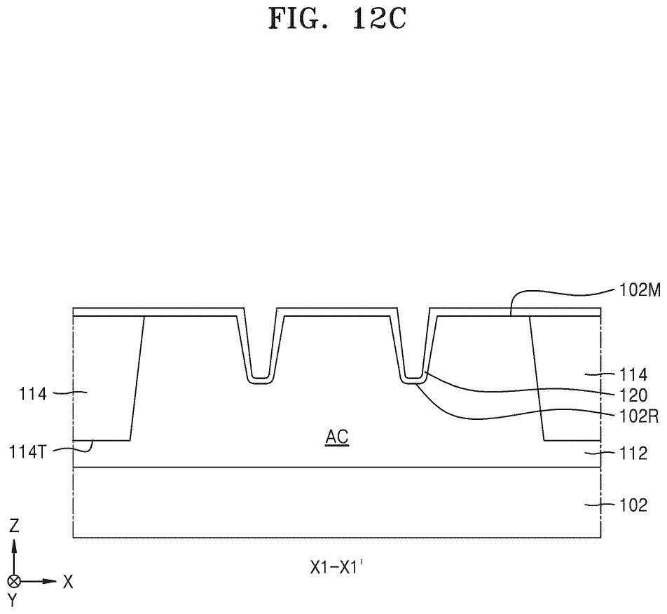

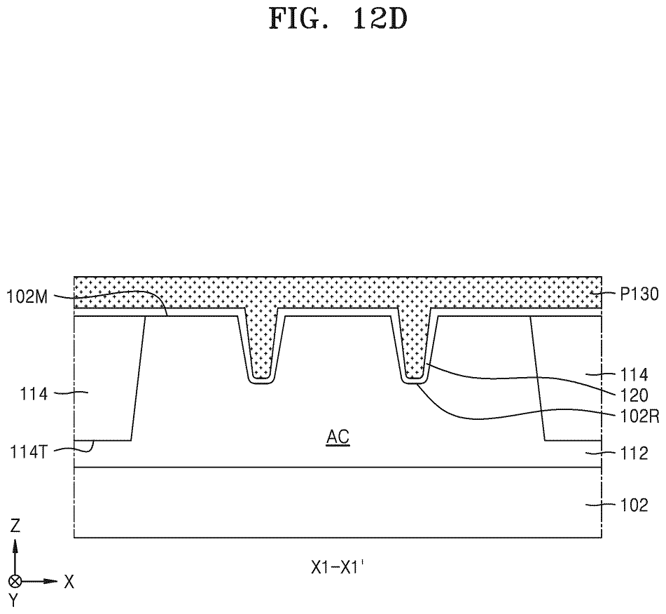

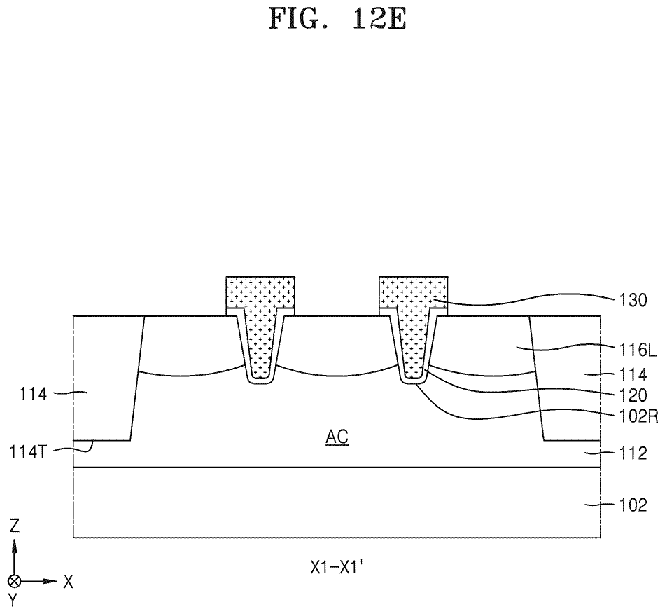

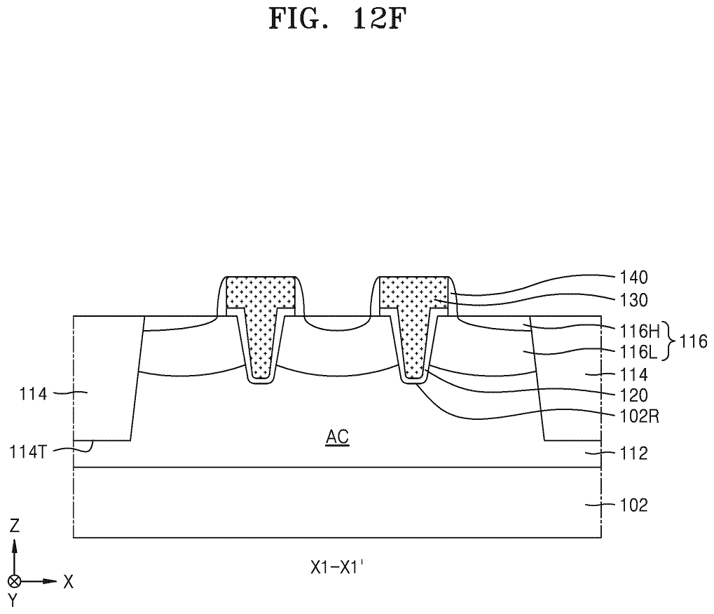

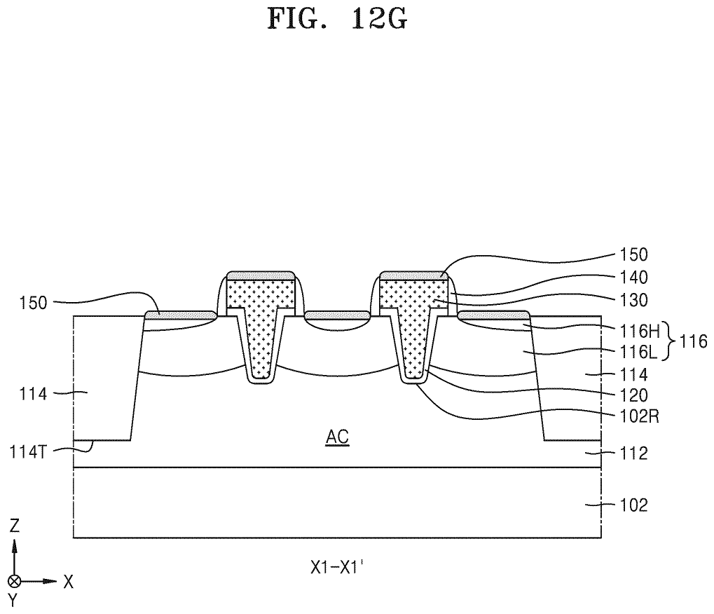

FIGS. 12A to 12G are cross-sectional views respectively illustrating a sequence of processes of a method of fabricating an integrated circuit device, according to embodiments. FIGS. 12A to 12G each illustrate components in a region corresponding to the cross-section taken along the line X1-X1′ of FIG. 1A, according to the sequence of processes. An example of a method of fabricating the integrated circuit device 100A shown in FIGS. 1A and 1B. In FIGS. 12A to 12G, the same reference numerals as in FIGS. 1A and 1B respectively denote the same members, and here, repeated descriptions thereof are omitted.

Referring to FIG. 12A, a well 112 of a first conductivity type may be formed by doping a portion of a substrate 102 with impurity ions. In an embodiment, phosphorus (P) ions are implanted into the substrate 102 to form the well 112 and set its first conductivity type to n-type.

Next, a trench region 114T may be formed by partially etching the substrate 102 from a main surface 102M of the substrate 102, and a device isolation film 114 may be formed by filling the trench region 114T. For example, the trench region 114T may be formed by removing portions of the substrate 102. An active region AC may be defined in the substrate 102 by the trench region 114T and the device isolation film 114.

In some embodiments, to form the trench region 114T in the substrate 102, a hardmask pattern may be formed on the substrate 102, and the substrate 102 may be etched by using the hardmask pattern as an etch mask. The hardmask pattern may have a structure in which an oxide film and a nitride film are sequentially stacked. A chemical vapor deposition (CVD) process may be used to form the device isolation film 114, but the inventive concept is not limited thereto.

Referring to FIG. 12B, a recess trench 102R may be formed in the active region AC by partially etching the substrate 102 in the active region AC from the main surface 102M of the substrate 102. As shown in FIG. 1A, the recess trench 102R may have a closed-loop shape in a plan view. For example, portions of the active region AC may be removed to form the recess trench 102R.

In some embodiments, the depth of the recess trench 102R in the vertical direction (the Z direction) may be variously adjusted as needed. In some embodiments, after forming the recess trench 102R, ions may be locally implanted into the active region AC through a lower surface of the recess trench 102R, resulting in formation of a drift ion-implanted region in a portion of the active region AC adjacent to the lower surface of the recess trench 102R. For example, when forming a recess channel transistor TRA (see FIGS. 1A and 1B) including a PMOS transistor is intended, p-type impurity ions may be implanted into the portion of the active region AC adjacent to the lower surface of the recess trench 102R to form the drift ion-implanted region.

Referring to FIG. 12C, in the resulting product of FIG. 12B, a gate dielectric film 120 may be formed to conformally cover an inner wall of the recess trench 102R and the main surface 102M of the substrate 102. A process including a thermal oxidation process, a CVD process, or a combination thereof may be used to form the gate dielectric film 120. In an embodiment, a thickness of the gate dielectric film 120 in this step is uniform or substantially uniform.

Referring to FIG. 12D, in the resulting product of FIG. 12C, a gate electrode layer P130 may be formed to cover the gate dielectric film 120. In some embodiments, the gate electrode layer P130 may include polysilicon. The gate electrode layer P130 may be formed on the gate dielectric film 120 to fill the remaining space of the recess trench 102R while covering the main surface 102M of the substrate 102 outside the recess trench 102R. For example, recesses in the gate dielectric film 120 may be filled with material of the gate electrode layer P130.

Referring to FIG. 12E, a gate electrode 130 may be formed by patterning the gate electrode layer P130, and the active region AC may be exposed by removing portions of the gate dielectric film 120, which are exposed around the gate electrode 130. As shown in FIG. 1A, the gate electrode 130 may have a closed-loop shape in a plan view. For example, the patterning may remove portions of the gate electrode layer P130.

Next, impurity ions of a second conductivity type that is opposite to the first conductivity type may be implanted into the gate electrode 130 and the active region AC. As a result, a lightly-doped region 116L may be formed in the active region AC. In some embodiments, when the second conductivity type is a p-type, boron (B) ions may be implanted into a portion of the well 112 to form the lightly-doped region 116L. In some embodiments, the lightly-doped region 116L may be formed in the manner of self-alignment by the gate electrode 130.

Referring to FIG. 12F, an insulating spacer 140 may be formed to cover respective sidewalls of the gate dielectric film 120 and the gate electrode 130, and impurity ions of the second conductivity type may be implanted into a portion of the lightly-doped region 116L at a relatively high concentration, thereby forming a heavily-doped region 116H. As a result, a source/drain region 116 may be formed in each of a first local region, which is surrounded by the gate electrode 130, of the active region AC and a second local region, which surrounds the gate electrode 130, of the active region AC. In an embodiment, an area or volume of the heavily-doped region 116H is smaller than an area or volume of the lightly-doped region 116L.

When the second conductivity type is a p-type, boron (B) ions may be implanted into the portion of the lightly-doped region 116L to form the heavily-doped region 116H. The heavily-doped region 116H may be formed in the manner of self-alignment by the insulating spacer 140.

Referring to FIG. 12G, by performing a salicide process on the resulting product of FIG. 12F, a plurality of metal silicide films 150 may be formed to cover the upper surface of the gate electrode 130 and the upper surface of the source/drain region 116. In an embodiment, the plurality of metal silicide films 150 are not formed on each of the insulating spacer 140 and the device isolation film 114.

Next, as shown in FIG. 1B, an interlayer dielectric 160 may be formed on the resulting product of FIG. 12G, followed by forming a plurality of source/drain contact plugs 172 and a plurality of gate contact plugs 174, which each pass through the interlayer dielectric 160 in the vertical direction (the Z direction) to be connected to a metal silicide film 150, and then, a plurality of wiring layers 180 may be formed on the interlayer dielectric 160, thereby fabricating the integrated circuit device 100A shown in FIGS. 1A and 1B. The plurality of wiring layers 180 may formed to contact the source/drain contact plugs 172.

Heretofore, although an example of the method of fabricating the integrated circuit device 100A shown in FIGS. 1A and 1B has been described with reference to FIGS. 12A to 12G, it will be understood by those of ordinary skill in the art that the integrated circuit devices 100B, 200, 300, 400, 500, 600, 700, 800, and 900 described with reference to FIGS. 2 to 10 may be fabricated by making various modifications and changes to the method described with reference to FIGS. 12A to 12G without departing from the spirit and scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate including an active region defined by a device isolation film;
a recess trench disposed in the active region and spaced apart from the device isolation film, the recess trench extending in a vertical direction from a main surface of the substrate towards an interior of the substrate; and
a recess channel transistor comprising a gate electrode disposed within the recess trench, the recess channel transistor including a channel positioned along a surface of the recess trench,
wherein each of the recess trench and the gate electrode has a closed-loop shape in a plan view.

2. The integrated circuit device of claim 1, wherein the recess channel transistor further comprises a gate dielectric film covering an inner wall of the recess trench,
the gate electrode comprises a buried electrode portion and a protruding electrode portion, the buried electrode portion being disposed on the gate dielectric film and within the recess trench, and the protruding electrode portion being integrally connected to the buried electrode portion and protruding above the main surface of the substrate, and
in a plan view, each of the buried electrode portion and the protruding electrode portion of the gate electrode is spaced apart from the device isolation film in a horizontal direction and is positioned entirely within the active region in the vertical direction.

3. The integrated circuit device of claim 1, wherein the active region comprises a first active region and a second active region, the first active region being surrounded by the recess trench, and the second active region being positioned between the recess trench and the device isolation film and surrounding the gate electrode,
the recess channel transistor further comprises:
a first source/drain region disposed in the first active region; and
a second source/drain region disposed in the second active region, and,
in a plan view, the second source/drain region has a closed-loop shape surrounding the gate electrode.

4. The integrated circuit device of claim 1, wherein the gate electrode comprises:
a buried electrode portion disposed within the recess trench; and
a protruding electrode portion integrally connected to the buried electrode portion and protruding above the main surface of the substrate, and,
in a width direction of the gate electrode, a first width of the protruding electrode portion is greater than a second width of the recess trench.

5. The integrated circuit device of claim 1, wherein the gate electrode comprises:
a buried electrode portion disposed within the recess trench; and
a protruding electrode portion integrally connected to the buried electrode portion and protruding above the main surface of the substrate, and,
in a width direction of the gate electrode, a first width of the protruding electrode portion is less than a second width of the recess trench.

6. The integrated circuit device of claim 1, further comprising a well disposed in the active region and accommodating the recess trench,
wherein the active region comprises a first active region and a second active region, the first active region being surrounded by the recess trench in a plan view, and the second active region being positioned between the recess trench and the device isolation film in a plan view, and
the recess channel transistor comprises:
a first source/drain region disposed in the first active region in the well;
a second source/drain region disposed in the second active region in the well; and
a channel region disposed in the well adjacent to a bottom of the recess trench.

7. The integrated circuit device of claim 6, wherein the recess channel transistor further comprises a gate dielectric film covering an inner wall of the recess trench, and
the gate dielectric film comprises a first portion disposed between the first source/drain region and the gate electrode and between the second source/drain region and the gate electrode and a second portion adjacent to the channel region, a thickness of the first portion being greater than a thickness of the second portion.

8. The integrated circuit device of claim 1, further comprising:
a first well having a first conductivity type and arranged in the substrate to accommodate the recess trench; and
a second well having a second conductivity type and accommodating the first well,
wherein the active region comprises a first active region and a second active region, the first active region being surrounded by the recess trench in a plan view, and the second active region being disposed between the recess trench and the device isolation film in a plan view, and
the recess channel transistor comprises:
a gate dielectric film covering an inner wall of the recess trench;
a first source/drain region disposed in the first active region in the first well;
a second source/drain region disposed in the second active region in the first well; and
a channel region disposed in the first well to be adjacent to a bottom of the recess trench.

9. The integrated circuit device of claim 1, wherein, in a plan view, the gate electrode has a quadrangular closed-loop shape with rounded corners.

10. The integrated circuit device of claim 1, wherein, in a plan view, the gate electrode has an elliptical closed-loop shape.

11. The integrated circuit device of claim 1, wherein, in a plan view, the gate electrode has a circular closed-loop shape.

12. An integrated circuit device comprising:
a substrate including an active region defined by a device isolation film; and
a recess channel transistor disposed in the active region,
wherein the recess channel transistor comprises:
a first recess trench disposed in the active region and spaced apart from the device isolation film, the first recess trench extending in a vertical direction from a main surface of the substrate towards an interior of the substrate;
a first gate electrode comprising a buried electrode portion and a protruding electrode portion, the buried electrode portion disposed within the first recess trench, and the protruding electrode portion being integrally connected to the buried electrode portion and protruding above the main surface of the substrate; and
a plurality of source/drain regions,
each of the first recess trench and the first gate electrode has a closed-loop shape in a plan view, and
one source/drain region among the plurality of source/drain regions is surrounded by the first gate electrode in a plan view.

13. The integrated circuit device of claim 12, wherein, in a plan view, each of the buried electrode portion and the protruding electrode portion of the first gate electrode is spaced apart from the device isolation film in a horizontal direction and is positioned entirely within the active region in the vertical direction.

14. The integrated circuit device of claim 12, wherein the active region comprises a first active region surrounded by the first recess trench and a second active region disposed between the first recess trench and the device isolation film, and
the plurality of source/drain regions comprise:
a first source/drain region disposed in the first active region; and
a second source/drain region disposed in the second active region.

15. The integrated circuit device of claim 12, wherein, in a plan view, the first gate electrode has a quadrangular closed-loop shape with rounded corners, an elliptical closed-loop shape, or a circular closed-loop shape.

16. The integrated circuit device of claim 12, wherein the recess channel transistor further comprises:
a second recess trench located in the active region, spaced apart from the device isolation film, and between the device isolation film and the first recess trench, the second recess trench extending in the vertical direction from the main surface of the substrate towards an interior of the substrate; and
a second gate electrode disposed within the second recess trench,
the second recess trench is disposed between the device isolation film and the first recess trench and surrounds the first recess trench,
the second gate electrode is disposed between the device isolation film and the first gate electrode and surrounds the first gate electrode, and
each of the second recess trench and the second gate electrode has a closed-loop shape in a plan view.

17. The integrated circuit device of claim 16, wherein the active region comprises a first active region surrounded by the first recess trench, a second active region disposed between the first recess trench and the second recess trench, and a third active region disposed between the second recess trench and the device isolation film, and
the plurality of source/drain regions comprise:
a first source/drain region disposed in the first active region;
a second source/drain region disposed in the second active region; and
a third source/drain region disposed in the third active region.

18. The integrated circuit device of claim 12, wherein the recess channel transistor further comprises a plurality of second gate electrodes disposed on the active region and spaced apart from, in a horizontal direction, each of the first gate electrode and the device isolation film,
each of the plurality of second gate electrodes has a closed-loop shape in a plan view, the plurality of second gate electrodes being spaced apart from each other in the horizontal direction, and
the first gate electrode and the plurality of second gate electrodes are connected to each other via a common gate terminal.

19. An integrated circuit device comprising:
a substrate including an active region defined by a device isolation film;
a recess trench disposed in the active region and spaced apart from the device isolation film, the recess trench extending in a vertical direction from a main surface of the substrate towards an interior of the substrate; and
a recess channel transistor including a channel positioned along a surface of the recess trench,
wherein the recess channel transistor comprises:
a gate dielectric film covering an inner wall of the recess trench;
a gate electrode comprising a buried electrode portion and a protruding electrode portion, the buried electrode portion being disposed on the gate dielectric film and within the recess trench, and the protruding electrode portion being integrally connected to the buried electrode portion and protruding above the main surface of the substrate;
a first source/drain region disposed in a first active region of the active region, the first active region being surrounded by the recess trench; and
a second source/drain region disposed in a second active region of the active region, the second active region being disposed between the recess trench and the device isolation film,
in a plan view, each of the buried electrode portion and the protruding electrode portion of the gate electrode is spaced apart from the device isolation film and is positioned entirely within the active region in the vertical direction, and
each of the recess trench, the gate electrode, and the second source/drain region has a closed-loop shape in a plan view.

20. The integrated circuit device of claim 19, wherein, in a plan view, the gate electrode has a quadrangular closed-loop shape with rounded corners, an elliptical closed-loop shape, or a circular closed-loop shape.
